(19) United States
(12) Patent Application Publication
(10) Pub. No.: US 2019/0218684 A1
(43) Pub. Date: Jul. 18, 2019

(54) METHOD FOR PRODUCING GALLIUM NITRIDE STACKED BODY

(71) Applicant: DEXERIALS CORPORATION, Tokyo (JP)

(72) Inventors: Makoto WATANABE, Tokyo (JP); Shinya AKIYAMA, Tokyo (JP)

(73) Assignee: DEXERIALS CORPORATION, Tokyo (JP)

(21) Appl. No.: 16/324,691

(22) PCT Filed: Sep. 6, 2017
(86) PCT No.: PCT/JP2017/032040

§ 371 Date: Feb. 11, 2019

(30) Foreign Application Priority Data
Sep. 12, 2016 (JP) 2016-177665

(51) Int. Cl. C30B 19/04; C30B 29/40; H01L 21/02

(52) U.S. Cl. CPC C30B 19/04; C30B 29/406; H01L 21/02625; H01L 21/02458; H01L 21/0254; H01L 21/0242

(57) ABSTRACT

There is provided a new and improved method for producing a gallium nitride stacked body that can produce a single-crystal layer with few crystal defects, the method including: an intermediate layer formation step of forming an intermediate layer (12) of gallium nitride with random crystal orientations on a substrate (11); and a single-crystal layer formation step of forming a single-crystal layer (13) of gallium nitride on the intermediate layer (12) by a liquid phase epitaxial growth method. Also the intermediate layer (12) may be formed by a liquid phase epitaxial growth method.

### TECHNICAL FIELD

The present invention relates to a method for producing a gallium nitride stacked body.

### BACKGROUND ART

These days, gallium nitride (GaN) is drawing attention as a semiconductor material for forming a blue light emitting diode, a semiconductor laser, a high-voltage, high-frequency power source integrated circuit (IC), or the like.

As methods for causing gallium nitride to be formed as a single-crystal layer on a sapphire substrate or the like, for example, the vapor phase growth methods disclosed in Patent Literatures 1 and 2 are known.

Such a gallium nitride crystal produced by vapor phase growth is produced by a method in which a gallium nitride crystal is synthesized directly from source materials in a gaseous state and is deposited on a substrate; therefore, is likely to experience mismatching between crystal lattices stochastically. Hence, in the produced gallium nitride crystal, a large number of crystal defects have occurred, and characteristics when it is incorporated in a device are reduced. For example, there has been a case where crystal defects occur at a density of approximately 10⁸/cm². Therefore, a method for producing a gallium nitride crystal in which few crystal defects occur has been demanded.

Thus, Patent Literature 3 proposes, as a method for producing a gallium nitride crystal in which crystal defects are less likely to occur, a method in which a single-crystal layer of gallium nitride is formed on a substrate by a liquid phase epitaxial growth method.

### CITATION LIST

### Patent Literature

Patent Literature 1: JP H8-310900A

Patent Literature 2: JP 2000-269605A

Patent Literature 3: JP 2015-71529A

### SUMMARY OF INVENTION

### Technical Problem

Meanwhile, in the technology disclosed in Patent Literature 3, a single-crystal layer of gallium nitride is formed directly on a substrate of sapphire or the like. For example, a single-crystal layer with crystal plane indices of (0 0 1) is formed on a substrate with crystal plane indices of (0 0 1) by forming a single-crystal layer of gallium nitride directly on the substrate. That is, a single-crystal layer having the same crystal orientation as the crystal orientation of a substrate is formed on the substrate by what is called a liquid phase heteroepitaxial growth method.

By the method disclosed in Patent Literature 3, the number of crystal defects is reduced as compared to that in vapor phase growth methods. However, even this method has been unable to sufficiently reduce the amount of crystal defects yet. Specifically, the lattice spacing of a substrate and the lattice spacing of a single-crystal layer are different in many cases. In particular, the difference between the spacings is very large when the substrate is a sapphire substrate. Consequently, there has been a case where regions with different crystal orientations occur in a single-crystal layer stochastically, due to such a difference between lattice spacings. For example, at the time when a single-crystal layer of gallium nitride is grown on a sapphire substrate with crystal plane indices of (0 0 1), there has been a case where a region where crystal growth progresses with crystal plane indices other than (0 0 1) exists in a region where crystal growth progresses with crystal plane indices of (0 0 1). Consequently, a discontinuous boundary surface is caused between regions of different crystal plane indices. The boundary surface is a kind of what is called a crystal defect.

In a single-crystal layer in which such crystal defects exist, the movement of electrons and holes is inhibited in the defective portions. Consequently, the single-crystal layer in which crystal defects exist cannot exhibit an expected function. Furthermore, such crystal defects can be a cause of cracks, peeling-off, etc.

Hence, for example, when what is called a template substrate in which a single-crystal layer is formed on a large-area substrate is produced, crystal defects like the above occur in a local manner, and consequently there has been a problem that the yield on completion is reduced.

Thus, the present invention has been made in view of the problem mentioned above, and an object of the present invention is to provide a new and improved method for producing a gallium nitride stacked body that can produce a single-crystal layer with few crystal defects.

### Solution to Problem

To solve the problem described above, according to an aspect of the present invention, there is provided a method for producing a gallium nitride stacked body including: an intermediate layer formation step of forming an intermediate layer of gallium nitride with random crystal orientations on a substrate; and a single-crystal layer formation step of forming a single-crystal layer of gallium nitride on the intermediate layer by a liquid phase epitaxial growth method.

Here, the single-crystal layer formation step may include a step of heating metal gallium and iron nitride in a nitrogen atmosphere to a heating temperature of more than 750° C., thereby preparing a source material melt, and a step of immersing, in the source material melt, the substrate on which the intermediate layer is formed.

In addition, the iron nitride may contain any one or more selected from the group consisting of tetrairon mononitride, triiron mononitride, and diiron mononitride.

In addition, the intermediate layer formation step may form the intermediate layer on the substrate by a liquid phase epitaxial growth method.

In addition, the intermediate layer formation step may include a step of heating metal gallium and iron nitride in a nitrogen atmosphere to a heating temperature of 550 to 750° C., thereby preparing a source material melt, and a step of immersing the substrate in the source material melt for more than or equal to 1 hour.

In addition, the iron nitride may contain any one or more selected from the group consisting of tetrairon mononitride, triiron mononitride, and diiron mononitride.

In addition, a thickness of the intermediate layer may be less than or equal to 150 nm.

In addition, the intermediate layer and the single-crystal layer may be formed on both surfaces of the substrate.

### Advantageous Effects of Invention

As described above, according to the present invention, the number of crystal defects in a single-crystal layer can be reduced because an intermediate layer serving as a buffer layer is interposed between a substrate and the single-crystal layer. The intermediate layer is presumed to have the function of easing the discrepancy between the lattice spacing of the single-crystal layer and the lattice spacing of the substrate.

### BRIEF DESCRIPTION OF DRAWINGS

FIG. 1 is a schematic diagram showing a cross-sectional structure of a gallium nitride stacked body according to a first embodiment of the present invention.

FIG. 2 is a graph showing an X-ray diffraction (XRD) spectrum of a single-crystal layer according to the first embodiment.

FIG. 3 is a cross-sectional transmission electron microscope (TEM) photograph of a gallium nitride stacked body.

FIG. 4 is a schematic diagram describing a configuration of a reaction apparatus used for production of a gallium nitride stacked body.

FIG. 5 is a schematic diagram showing a cross-sectional structure of a gallium nitride stacked body according to a second embodiment.

FIG. 6 is a schematic diagram showing a configuration of a jig used for production of a gallium nitride stacked body according to the second embodiment.

FIG. 7 is a graph showing a temperature profile at a time of heating in Example.

FIG. 8 is a graph showing XRD spectra of gallium nitride crystals for some heating temperatures.

FIG. 9 is a graph showing an XRD spectrum of a single-crystal layer according to Comparative Example.

FIG. 10 is a schematic diagram showing a surface structure of a single-crystal layer produced by a conventional liquid phase epitaxial growth method.

FIG. 11 is a surface form profile of the amount of warpage deformation of a gallium nitride stacked body according to Example, which is measured by a non-contact precision external form measuring apparatus.

FIG. 12 is a surface form profile of the amount of warpage deformation of a commercially available gallium nitride stacked body, which is measured by a non-contact precision external form measuring apparatus.

### DESCRIPTION OF EMBODIMENTS

Hereinafter, (a) preferred embodiment(s) of the present invention will be described in detail with reference to the appended drawings. Note that, in this specification and the appended drawings, structural elements that have substantially the same function and structure are denoted with the same reference numerals, and repeated explanation of these structural elements is omitted.

### 1. First Embodiment

### (1-1. Structure of Gallium Nitride Stacked Body)

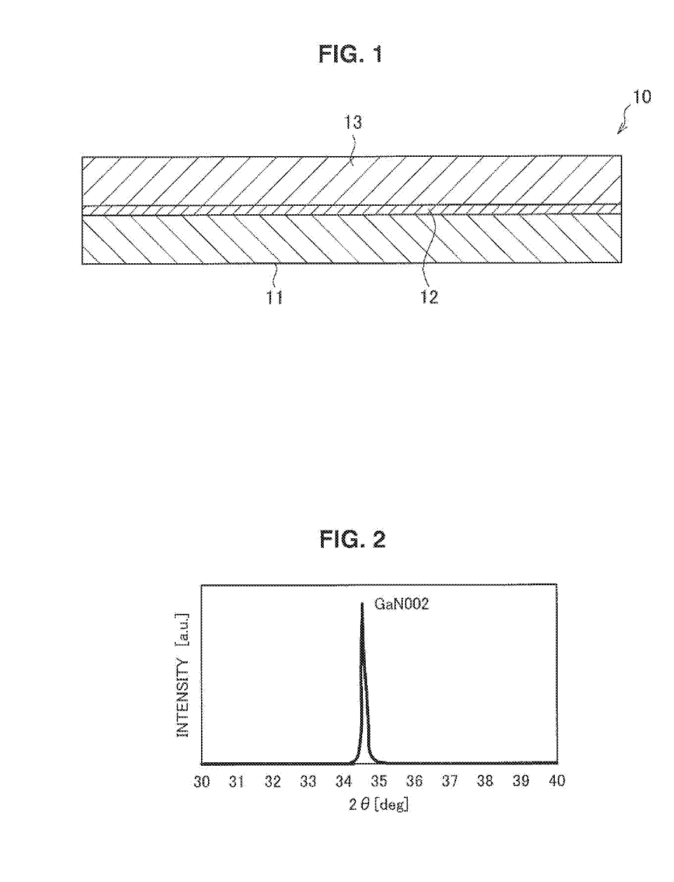

First, the structure of a gallium nitride stacked body 10 according to a first embodiment is described on the basis of FIG. 1 and FIG. 2.

The gallium nitride stacked body 10 according to the first embodiment includes a substrate 11, an intermediate layer 12, and a single-crystal layer 13. The type of the substrate 11 is not particularly questioned, and is not particularly limited as long as it is a substrate on which the intermediate layer 12 and the single-crystal layer 13 according to the present embodiment can be stacked. For example, a substrate that can be used for a conventional gallium nitride stacked body is given as the substrate 11. More specifically, the substrate 11 may be a sapphire substrate, silicon carbide (SiC), zinc oxide (ZnO), or the like. The crystal defect described above is likely to occur particularly when a single-crystal layer of gallium nitride is formed directly on a sapphire substrate. Thus, the effect by the first embodiment can be exhibited more favorably when a sapphire substrate is used as the substrate 11.

The shape of the substrate 11 may be any shape, and may be a substantially flat plate-like shape, a substantially circular plate-like shape, or the like, for example.

The intermediate layer 12 is interposed between the single-crystal layer 13 and the substrate 11. The intermediate layer 12 plays a role as what is called a buffer layer. The intermediate layer 12 is formed of a crystal of gallium nitride with random crystal orientations. That is, the intermediate layer 12 is a polycrystalline substance of gallium nitride, and is an aggregate of a plurality of crystal grains. The crystal orientations of the crystal grains are different from each other. In the first embodiment, the number of crystal defects in the single-crystal layer 13 can be reduced by interposing such an intermediate layer 12 between the single-crystal layer 13 and the substrate 11. The intermediate layer 12 is presumed to have the function of easing the discrepancy between the lattice spacing of the single-crystal layer 13 and the lattice spacing of the substrate 11.

The thickness of the intermediate layer 12 is not particularly limited, but is preferably 10 to 150 nm. If the thickness of the intermediate layer 12 is less than 10 nm, the function of the intermediate layer 12 may not be exhibited sufficiently. That is, crystal defects may occur in the single-crystal layer 13. On the other hand, if the thickness of the intermediate layer 12 is more than 150 nm, unevenness may occur in the thickness of the single-crystal layer 13. Thus, the thickness of the intermediate layer 12 is preferably less than 150 nm.

Although details are described later, such an intermediate layer 12 is formed on the substrate 11 by what is called a liquid phase epitaxial growth method. That is, the intermediate layer 12 is formed on the substrate 11 by causing the substrate 11 to be immersed in a source material melt.

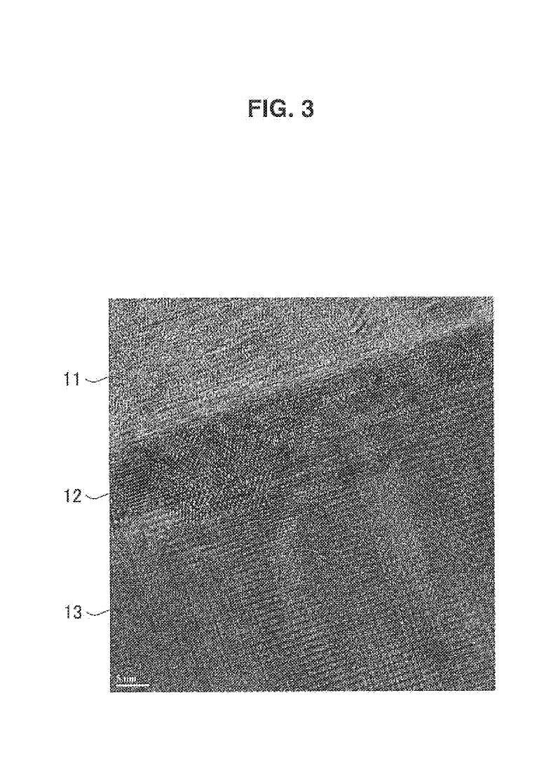

The fact that the intermediate layer 12 is formed can be checked by, for example, observing a cross section of the gallium nitride stacked body 10 with a TEM. FIG. 3 shows an example of a cross-sectional TEM photograph (with a magnifying power of two million) of the gallium nitride stacked body 10. As is clear from FIG. 3, it is confirmed that the intermediate layer 12 is formed between the substrate 11 (in this example, a sapphire substrate) and the single-crystal layer 13. This cross-sectional TEM photograph is a cross-sectional TEM photograph of Example 1 described later.

The single-crystal layer 13 is a single-crystal layer of gallium nitride. In the first embodiment, the single-crystal layer 13 is formed on the intermediate layer 12, and is therefore a high-quality single-crystal layer with a uniform crystal orientation. That is, in the single-crystal layer 13, no crystal defects exist, or the number of crystal defects, if any, is much smaller than in the past. For example, in the case where the crystal plane of the substrate 11 is (0 0 1), also the crystal plane of the single-crystal layer 13 is (0 0 1), and few crystal defects exist in the single-crystal layer 13. The thickness of the single-crystal layer 13 is not particularly limited, and may be adjusted in accordance with a function, etc. required of the single-crystal layer 13, as appropriate.

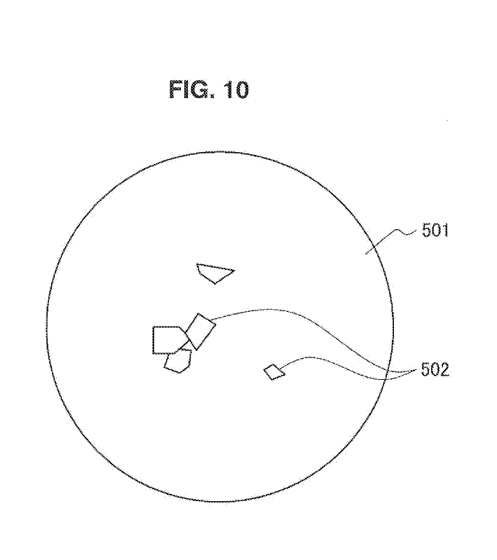

The fact that few crystal defects exist in the single-crystal layer 13 can be checked by an X-ray crystal structure analysis. FIG. 2 shows an example of an XRD spectrum of the single-crystal layer 13. As is clear from this example, a large peak is observed only around 34.6° in the XRD spectrum of the single-crystal layer 13, and this peak corresponds to the crystal plane of (0 0 1). This XRD spectrum is an XRD spectrum of Example 1 described later. For comparison, an example of an XRD spectrum in the case where a single-crystal layer is formed directly on the substrate 11 (in practice, a very thin intermediate layer is formed) is shown in FIG. 9. In the XRD spectrum shown in FIG. 9, not only a peak corresponding to GaN(0 0 2) but also a peak corresponding to GaN(2 0 0) and a peak corresponding to the crystal orientation of GaN(1 0 −1 0) are observed. Thus, in this example, the single-crystal layer is inferred to have the structure shown in FIG. 10. That is, the single-crystal layer has crystalline region 501 having the crystal plane of (0 0 1) and crystalline regions 502 each having the crystal plane of (1 0 0) or (1 0 −1 0). Such mismatching between crystal orientations is presumed to stochastically occur due to a difference between the lattice spacings of the substrate 11 and the single-crystal layer. Then, a discontinuous boundary surface, that is, a crystal defect is formed between crystalline region 501 and crystalline region 502. The XRD spectrum shown in FIG. 9 is an XRD spectrum of Comparative Example 1 described later.

### (1-2. Reaction Apparatus for Gallium Nitride Stacked Body)

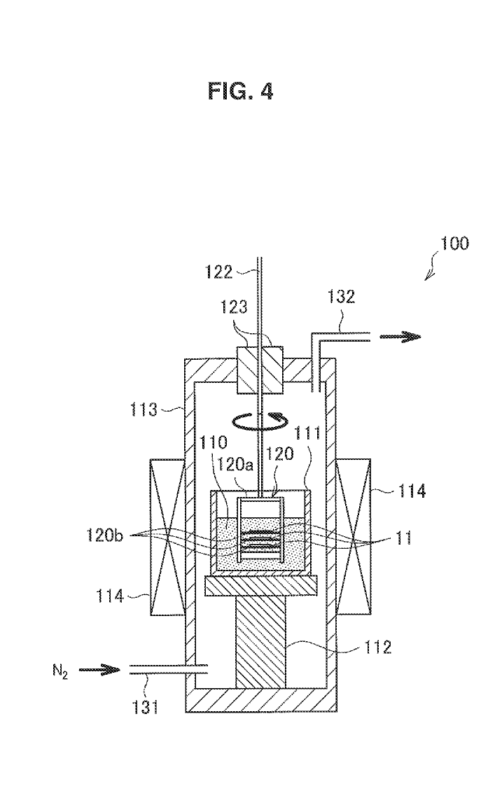

Next, a reaction apparatus 100 used in a method for producing a gallium nitride crystal according to the first embodiment is described with reference to FIG. 4. FIG. 4 is a schematic diagram describing the configuration of the reaction apparatus 100 used for the production of a gallium nitride crystal.

As shown in FIG. 4, the reaction apparatus 100 includes an electric furnace 113, a heater 114 provided on the side surface of the electric furnace 113, a gas introduction port 131, a gas exhaust port 132, a lifting shaft 122, and a sealing material 123 that ensures airtightness between the lifting shaft 122 and the electric furnace 113. A reaction vessel 111 in which a source material melt 110 is contained is placed still on a base 112 in the interior of the electric furnace 113. A holder 120 is provided at one end of the lifting shaft 122, and the substrate 11 is held by the holder 120.

The reaction apparatus 100 is an apparatus that epitaxially grows the intermediate layer 12 and the single-crystal layer 13 of gallium nitride on the substrate 11 immersed in the source material melt 110.

The electric furnace 113 has a sealed-up structure, and houses the reaction vessel 111 in the interior. For example, the electric furnace 113 may be a cylindrical structure with an inner diameter (diameter) of approximately 200 mm and a height of approximately 800 mm. The heater 114 is placed on the side surface in the longitudinal direction of the electric furnace 113, and heats the interior of the electric furnace 113.

The gas introduction port 131 is provided in a lower portion of the electric furnace 113, and introduces an atmosphere gas (for example, N₂ gas) into the electric furnace 113. The gas exhaust port 132 is provided in an upper portion of the electric furnace 113, and exhausts the atmosphere gas from the interior of the electric furnace 113. By the gas introduction port 131 and the gas exhaust port 132, the interior of the electric furnace 113 is kept to be an atmosphere of approximately normal pressure (that is, atmospheric pressure).

The base 112 supports the reaction vessel 111. Specifically, the base 112 supports the reaction vessel 111 in such a manner that the reaction vessel 111 is equally heated by the heater 114. For example, the height of the base 112 may be a height whereby the reaction vessel 111 is located on a central portion of the heater 114.

The reaction vessel 111 is a vessel that holds a source material melt 110 obtained by melting reaction materials by heating. The reaction vessel 111 may be a cylindrical vessel with an outer diameter (diameter) of approximately 100 mm, a height of approximately 90 mm, and a thickness of approximately 5 mm, for example. The material of the reaction vessel 111 is preferably a material that does not react with metal gallium. In particular, the material of the reaction vessel 111 is more preferably boron nitride or graphite in order to prevent an impurity such as oxygen from being mixed in the source material melt 110.

The source material melt 110 is a liquid obtained by melting reaction materials. Specifically, the source material melt 110 is a liquid obtained by heating and melting a mixed powder of metal gallium and iron nitride, which are reaction materials, with the heater 114.

Here, as the metal gallium, high-purity metal gallium is preferably used, and commercially available metal gallium with a purity of more than or equal to approximately 99.99% may be used, for example.

As the iron nitride, specifically, tetrairon mononitride (Fe₄N), triiron mononitride (Fe₃N), or diiron mononitride (Fe₂N), or a mixture of two or more of these may be used. As the iron nitride, high-purity iron nitride is preferably used, and commercially available iron nitride with a purity of more than or equal to approximately 99.9% may be used.

Iron atoms in the iron nitride function as a catalyst by being mixed with metal gallium and heated, and produce active nitrogen from nitrogen atoms in the melt or nitrogen molecules in the atmosphere gas. The produced active nitrogen reacts with metal gallium easily; thus, the synthesis of a gallium nitride crystal can be promoted. That is, since iron nitride functions as a catalyst, the concentration of iron nitride in the reaction materials is not particularly limited, and it is sufficient for iron nitride to be contained at least in the reaction materials.

Specifically, in the case where tetrairon mononitride is used as the iron nitride, the iron nitride reacts with metal gallium by the nitriding action of tetrairon mononitride, and produces a gallium nitride crystal (Reaction Formula 1).

Fe₄N+13Ga->GaN+4FeGa₃ Reaction Formula 1

A nitrogen molecule that is dissolved in the melt from the nitrogen atmosphere reacts with metal gallium by an iron atom functioning as a catalyst, and produces a gallium nitride crystal (Reaction Formula 2).

2Ga+N₂+Fe->2GaN+Fe Reaction Formula 2

The mixing ratio between metal gallium and iron nitride may be, for example, a ratio whereby the proportion of the mole number of the iron element in the iron nitride to the total mole number of metal gallium and the iron element of the iron nitride is more than or equal to 0.1% and less than or equal to 50%. If the proportion of the iron element is less than 0.1%, the amount of the iron element, which is a catalyst, is small, and the rate of growth of the gallium nitride crystal is slow. If the proportion of the iron element is more than 50%, not only gallium nitride but also gallium oxide or the like is produced, and the growth of the gallium nitride crystal may be inhibited.

For example, in the case where tetrairon mononitride is used as the iron nitride, the ratio between the mole numbers of metal gallium and tetrairon mononitride may be set to approximately 99.97:0.03 to 80:20 in order to satisfy the proportion of the mole number of the iron element in the iron nitride mentioned above.

In the case where triiron mononitride or diiron mononitride is used as the iron nitride, the ratio of the mole number described above may be converted in accordance with the proportion between the iron element and the nitrogen element in the iron nitride. For example, in the case where triiron mononitride is used as the iron nitride, the ratio between the mole numbers of metal gallium and triiron mononitride may be set to approximately 99.96:0.04 to 75:25. In the case where diiron mononitride is used as the iron nitride, the ratio between the mole numbers of metal gallium and diiron mononitride may be set to approximately 99.94:0.06 to 67.5:32.5.

The lifting shaft 122 immerses the substrate 11 in the source material melt 110, and lifts the substrate 11 from the source material melt 110. Specifically, the lifting shaft 122 is provided to pierce the upper surface of the electric furnace 113. The holder 120 that holds the substrate 11 is provided at one end of the lifting shaft 122 in the interior of the electric furnace 113.

The lifting shaft 122 may be provided to be rotatable with the shaft as the center. In such a case, by rotating the lifting shaft 122, the substrate 11 can be rotated, and the source material melt 110 can be stirred. Thereby, the nitrogen concentration distribution in the source material melt 110 can be made more uniform, and accordingly a more homogeneous single-crystal layer 13 of gallium nitride can be grown.

The holder 120 includes a frame body 120a and a plurality of shelf boards 120b held in the frame body 120a. The material of the holder 120 is preferably a material that does not react with metal gallium. Specifically, a material similar to the material of the reaction vessel, namely, boron nitride or graphite is preferable.

The frame body 120a is linked to the lifting shaft 122. Substrates 11 are set individually on the shelf boards 120b. Thereby, the intermediate layer 12 and the single-crystal layer 13 are sequentially formed on the exposed surface of the substrate 11. The exposed surface of the substrate 11 is mirror-polished in advance.

The sealing material 123 is provided between the lifting shaft 122 and the electric furnace 113, and ensures the airtightness of the interior of the electric furnace 113. Since an event in which the air outside the electric furnace 113 flows into the electric furnace 113 can be prevented by the sealing material 123, the reaction apparatus 100 can set the interior of the electric furnace 113 to a gas atmosphere (for example, a nitrogen atmosphere) introduced from the gas introduction port 131.

By the above configuration, the reaction apparatus 100 can raise and lower the lifting shaft 122 to immerse the substrate 11 in the source material melt 110, and can sequentially form the intermediate layer 12 and the single-crystal layer 13 of gallium nitride on the substrate 11. Although details are described later, the intermediate layer 12 and the single-crystal layer 13 can be formed on the substrate 11 by adjusting the heating temperature of the source materials. Further, the thicknesses of the intermediate layer 12 and the single-crystal layer 13 can be adjusted by adjusting the heating temperature and the immersion time.

### (1-3. Method for Producing Gallium Nitride Stacked Body)

Next, a method for producing a gallium nitride stacked body is described. First, powders of metal gallium and iron nitride are mixed together and are put into the reaction vessel 111 described above, and the reaction vessel 111 is mounted in the electric furnace 113.

Here, the iron nitride preferably contains any one or more selected from the group consisting of tetrairon mononitride, triiron mononitride, and diiron mononitride.

Subsequently, nitrogen gas is introduced into the electric furnace 113 from the gas introduction port 131, and the interior of the electric furnace 113 is set to a nitrogen atmosphere.

Next, an intermediate layer formation step that forms the intermediate layer 12 on the substrate 11 is performed. Specifically, the mixed source material in the reaction vessel 111 is heated by the heater 114. Nitrogen gas introduced in the electric furnace 113 is exhausted from the gas exhaust port 132, and thus the interior of the electric furnace 113 is kept at approximately normal pressure.

Here, the mixed source material in the reaction vessel 111 is heated to a heating temperature of 550 to 750° C. Thereby, the melt of the mixed source material, that is, the source material melt 110 is produced. If the reaction temperature of the mixed source material is less than 550° C., almost no crystals of gallium nitride are precipitated on the substrate 11. On the other hand, if the heating temperature of the mixed source material is more than 750° C., the single-crystal layer 13 is directly formed on the substrate 11. Here, it is preferable that the heating temperature be kept at 550 to 750° C. during the time when the intermediate layer 12 is being formed on the substrate 11. The heating temperature does not need to be constant, and may vary as long as it is within the range of 550 to 750° C. The rate of temperature increase of the mixed source material is not particularly limited, either.

After the reaction materials in the reaction vessel 111 melt and become the source material melt 110, the lifting shaft 122 is operated, thereby immersing the substrate 11 held by the holder 120 in the source material melt 110. Thus, the intermediate layer 12 is formed on the substrate 11 immersed in the source material melt 110. Here, the thickness of the intermediate layer 12 can be adjusted by adjusting the heating temperature of the source material melt 110 and the immersion time of the substrate 11. As an example, when the heating temperature is set to 700° C. and the immersion time is set to 6 hours, the thickness of the intermediate layer 12 is approximately 15 nm. The immersion time is preferably more than or equal to 1 hour. This is because, if the immersion time is too short, an intermediate layer 12 with a sufficient thickness may not be formed.

Subsequently, a single-crystal layer formation step is performed. Specifically, the source material melt 110 is heated to a heating temperature of more than 750° C. The upper limit value of the heating temperature is not particularly limited, but is preferably less than or equal to 1000° C. This is because, if the heating temperature of the source material melt 110 is more than 1000° C., a mass reduction, which is presumed to be due to the evaporation of metal gallium from the source material melt 110, occurs. Thereby, the single-crystal layer 13 is formed on the intermediate layer 12. In the first embodiment, since the single-crystal layer 13 is formed on the intermediate layer 12, the number of crystal defects in the single-crystal layer 13 can be reduced. That is, the crystal orientation of the single-crystal layer 13 can be made more uniform. The crystal orientation of the single-crystal layer 13 coincides with the crystal orientation of the substrate 11.

Here, it is preferable that the heating temperature be kept within the range of the heating temperatures described above (that is, more than 750° C.; the upper limit value being preferably less than or equal to 1000° C.) during the time when the single-crystal layer 13 is being formed on the intermediate layer 12. The heating temperature does not need to be constant, and may vary as long as it is within the range of the heating temperatures described above. The rate of temperature increase of the source material melt 110 is not particularly limited, either. Here, the thickness of the single-crystal layer 13 can be adjusted by adjusting the heating temperature of the source material melt 110 and the immersion time of the substrate 11.

The gallium nitride stacked body 10 is produced by the above steps. The produced gallium nitride stacked body 10 is lifted from the source material melt, and is cooled to room temperature. There is a case where a by-product such as an intermetallic compound of iron and gallium is contained in the gallium nitride stacked body 10 obtained by the steps mentioned above. Thus, a purification step described below may be further performed on the gallium nitride stacked body 10. The purification step is performed by, for example, cleaning the gallium nitride stacked body 10 with an acid such as aqua regia.

By the above steps, the intermediate layer 12 and the single-crystal layer 13 of gallium nitride can be produced efficiently by liquid phase epitaxial growth in a nitrogen atmosphere of low pressure such as normal pressure. Furthermore, the intermediate layer 12 and the single-crystal layer 13 can be formed on the substrate 11 by simply adjusting the temperature of the source material melt 110; thus, the intermediate layer 12 and the single-crystal layer 13 can be formed on the substrate 11 easily.

Although in the above step the intermediate layer 12 is formed on the substrate 11 by a liquid phase epitaxial growth method, the intermediate layer 12 may be formed on the substrate 11 by other methods, such as a vapor phase epitaxial growth method. However, by forming the intermediate layer 12 by a liquid phase epitaxial growth method, the intermediate layer 12 and the single-crystal layer 13 can be formed by a continuous process in the same reaction apparatus.

### 2. Second Embodiment

### (2-1. Structure of Gallium Nitride Stacked Body)

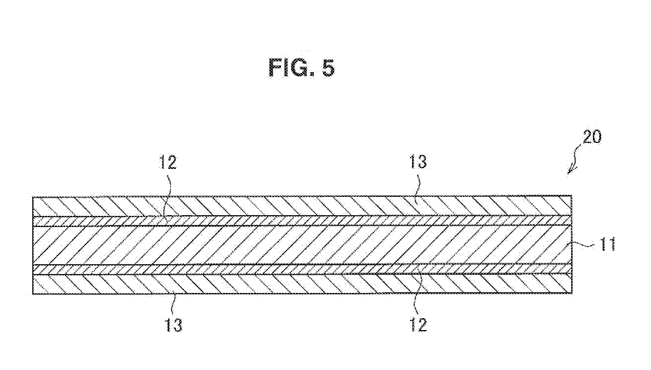

Next, the structure of a gallium nitride stacked body 20 according to a second embodiment is described on the basis of FIG. 5. The gallium nitride stacked body 20 includes the substrate 11, intermediate layers 12 formed individually on both surfaces of the substrate 11, and single-crystal layers 13 formed individually on the surfaces of the intermediate layers 12. Detailed structures of the intermediate layer 12 and the single-crystal layer 13 are similar to those of the first embodiment. Thus, the gallium nitride stacked body 20 according to the second embodiment has a structure symmetrical in the thickness direction, and therefore experiences less warpage. That is, in the case where the intermediate layer 12 and the single-crystal layer 13 are formed only on one surface of the substrate 11, there is a case where warpage due to a difference in thermal expansion coefficient between the substrate 11 and gallium nitride occurs. For example, in the case where the substrate 11 is a sapphire substrate, the thermal expansion coefficient is different between gallium nitride and sapphire by approximately 2×10⁻⁶ [° C.⁻¹], and the magnitude of thermal shrinkage is different. Hence, compressive stress occurs on the gallium nitride side, and deformation may occur such that the gallium nitride side is convex. The second embodiment has a shape symmetrical in the thickness direction because the intermediate layer 12 and the single-crystal layer 13 are formed on both surfaces of the substrate 11. Hence, the warpage of the gallium nitride stacked body 20 is reduced. In a field where the single-crystal layer 13 of gallium nitride is used, particularly in a semiconductor element, the flatness of the single-crystal layer 13 is required particularly strongly. This is because a demand to build a fine structure on the single-crystal layer 13 is very strong. If large warpage has occurred on the single-crystal layer 13, such warpage is a very large obstacle when performing fine processing. Further, the magnitude of warpage increases as the size (diameter) of the substrate 11 becomes larger. Thus, it is very important that the warpage of the single-crystal layer 13 be reduced.

### (2-2. Reaction Apparatus for Gallium Nitride Stacked Body)

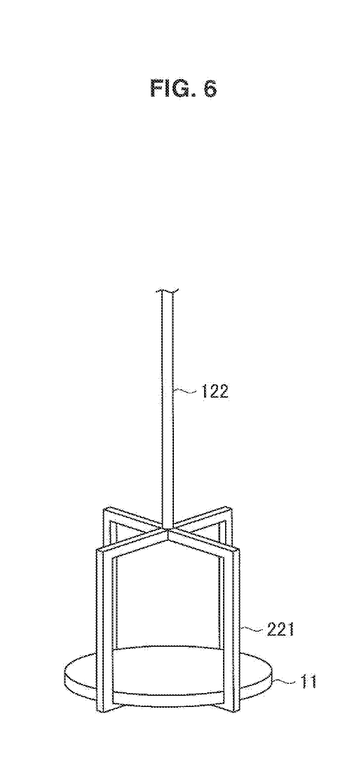

Next, the configuration of a reaction apparatus for the gallium nitride stacked body 20 is described. The reaction apparatus according to the second embodiment is one in which the holder 120 of the reaction apparatus of FIG. 4 is replaced with a holder 221 shown in FIG. 6. The holder 221 includes a plurality of hook-like arm members, and holds the substrate 11 from lateral sides. The front and back surfaces of the substrate 11 can be exposed to the source material melt 110. Thereby, the intermediate layer 12 and the single-crystal layer 13 can be formed on each of the front and back surfaces of the substrate 11.

### (2-3. Method for Producing Gallium Nitride Stacked Body)

A method for producing the gallium nitride stacked body 20 is similar to the method of the first embodiment except that the holder 120 is replaced with the holder 221. However, the front and back surfaces of the substrate 11 are mirror-polished in advance. A gallium nitride stacked body similar to the gallium nitride stacked body of the first embodiment can be produced also when only one surface of the substrate 11 is mirror-polished. Thus, according to the second embodiment, the intermediate layer 12 and the single-crystal layer 13 can be simultaneously formed on both surfaces of the substrate 11 by a very simple method. Furthermore, the steps of the second embodiment are steps almost similar to the steps of the first embodiment, and hence the cost increase from the first embodiment can be suppressed to a very low level.

### EXAMPLES

In the following, the first and second embodiments are described more specifically with reference to Examples. Examples shown below are condition examples for describing the feasibility and effect of the first and second embodiments, and the present invention is not limited to Examples below.

### 1. Example 1

Next, Example 1 is described. Example 1 corresponds to Example of the first embodiment. In Example 1, the gallium nitride stacked body 10 was produced using the reaction apparatus 100 and the holder 120 described above.

Specifically, a metal gallium reagent with a purity of 7N (produced by 5N Plus Inc.) was prepared as metal gallium, and a triiron nitride reagent with a purity of more than or equal to 99% (produced by Kojundo Chemical Co., Ltd.) was prepared as iron nitride. Further, a sapphire substrate of which the crystal plane was (0 0 1), the diameter was approximately 2 inches, and the thickness was approximately 0.4 mm was prepared as the substrate 11.

Then, powders of the metal gallium and the iron nitride were mixed together and were put into the reaction vessel 111 described above, and the reaction vessel 111 was mounted in the electric furnace 113. Here, the molar ratio between the metal gallium and the iron nitride was set to 99.9:0.1. The material of the reaction vessel 111 was graphite.

Subsequently, nitrogen gas with a purity of 99.99% was introduced into the electric furnace 113 from the gas introduction port 131, and the interior of the electric furnace 113 was set to a nitrogen atmosphere. The flow rate of nitrogen gas was set to 5 liters per minute. Nitrogen gas introduced in the electric furnace 113 is exhausted from the gas exhaust port 132, and thus the interior of the electric furnace 113 is kept at approximately normal pressure.

Next, the intermediate layer formation step that forms the intermediate layer 12 on the substrate 11 was performed. Specifically, the mixed source material in the reaction vessel 111 was heated by the heater 114 to 700° C. at a rate of temperature increase of 300° C./hour. Thereby, the source material melt 110 was produced.

Next, the lifting shaft 122 was operated, thereby immersing the substrate 11 held by the holder 120 in the source material melt 110. Here, the exposed surface of the substrate 11 had been mirror-polished in advance. The material of the holder 120 was graphite. Next, this state was held for 6 hours. Thereby, the intermediate layer 12 was formed on the substrate 11. The substrate 11 was rotated at a rate of 5 rotations per minute during the formation of the intermediate layer 12 and the single-crystal layer 13.

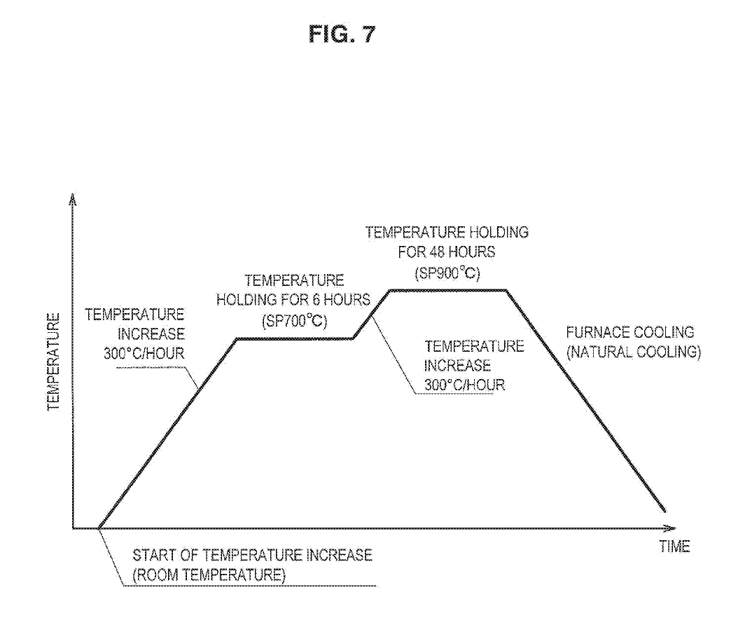

Subsequently, the single-crystal layer formation step was performed. Specifically, while the substrate 11 was immersed in the source material melt 110, the source material melt 110 was heated to 900° C. at a rate of temperature increase of 300° C./hour. Next, this state was held for 48 hours. Thus, the single-crystal layer 13 was formed on the intermediate layer 12. That is, the gallium nitride stacked body 10 was produced. Next, the produced gallium nitride stacked body 10 was lifted from the source material melt 110, and was cooled to room temperature. Next, the gallium nitride stacked body 10 was purified. The temperature profile of the above steps is shown in FIG. 7.

Next, a cross section of the gallium nitride stacked body 10 was observed with a TEM (HF-3300, produced by Hitachi High-Technologies Corporation) in order to check that the gallium nitride stacked body 10 included the intermediate layer 12 and the single-crystal layer 13. The result is shown in FIG. 3. As is clear from FIG. 3, it has been confirmed that the intermediate layer 12 and the single-crystal layer 13 are formed on the substrate 11.

Next, an X-ray diffraction analysis of the single-crystal layer 13 was performed using an XRD apparatus (Rigaku Corporation, RINT2500) in order to check the crystal orientation of the single-crystal layer 13. The result is shown in FIG. 2. As is clear from FIG. 2, a large peak is observed only around 34.6° in the XRD spectrum of the single-crystal layer 13, and this peak corresponds to GaN(0 0 2). Thus, it has been confirmed that the crystal plane of the single-crystal layer 13 is uniform as (0 0 1) and that few or no crystal defects exist.

### 2. Comparative Example 1

Next, Comparative Example 1 below was performed for comparison with Example 1. In Comparative Example 1, the intermediate layer formation step was omitted from the steps of Example 1. That is, a single-crystal layer was formed directly on the substrate 11 (in practice, a very thin intermediate layer was formed). Then, an X-ray diffraction analysis of the resulting single-crystal layer was performed. The result is shown in FIG. 9. In the XRD spectrum shown in FIG. 9, not only a peak corresponding to GaN(0 0 2) but also a peak corresponding to GaN(2 0 0) and a peak corresponding to GaN(1 0 −1 0) were observed. Therefore, in Comparative Example 1, crystalline regions having (1 0 0) and (1 0 −1 0), which are crystal planes other than (0 0 1), coexist in the single-crystal layer. Thus, it can be said that a large number of lattice spacings exist in the single-crystal layer.

### 3. Verification of Temperature Range for Forming Intermediate Layer (Experimental Example)

Next, the temperature range in which the intermediate layer 12 is formed was verified. The reaction apparatus used in the present verification is roughly as follows. The reaction apparatus includes a laterally extending tubular furnace and an electric furnace placed on the circumferential surface of the tubular furnace. The interior of the tubular furnace is heated by the electric furnace. Then, in the present verification, a crucible made of graphite was filled with the mixed source material used in Example 1. That is, this mixed source material is a mixture of metal gallium and iron nitride. The metal gallium is a metal gallium reagent with a purity of 7N (produced by 5N Plus Inc.), and the iron nitride is a triiron nitride reagent with a purity of more than or equal to 99% (produced by Kojundo Chemical Co., Ltd.).

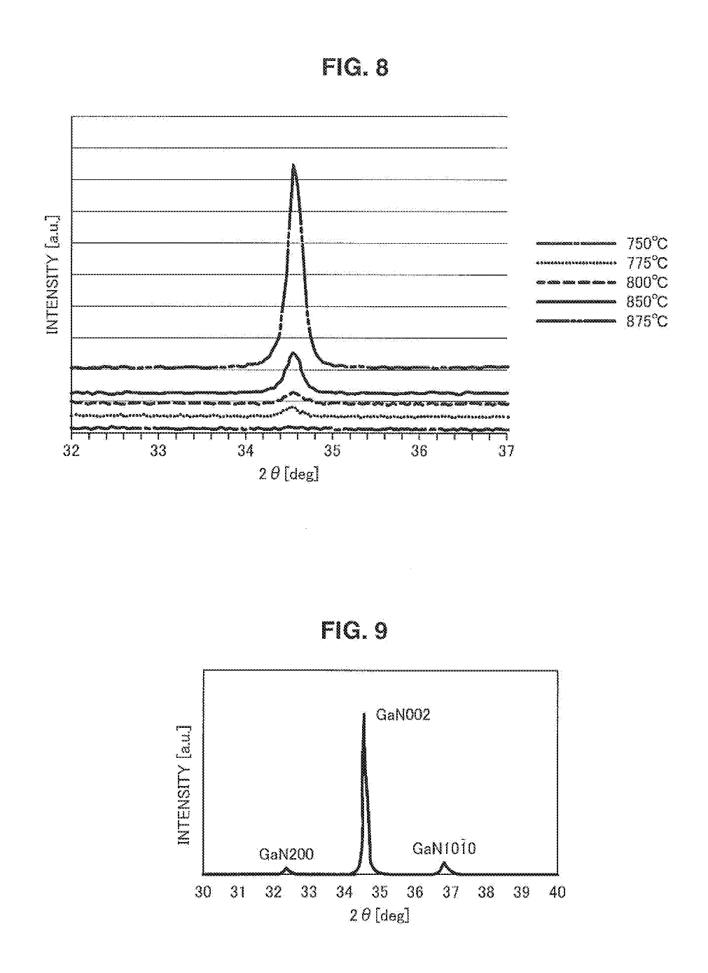

Next, the crucible filled with the mixed source material was inserted into the tubular furnace, and the mixed source material was held for 6 hours at a reaction temperature of any one of 750° C., 775° C., 800° C., 850° C., and 875° C. During the temperature holding, nitrogen gas was circulated through the interior of the tubular furnace at a flow rate of 5 liters per minute. Next, the crucible was cooled to room temperature, and then the residual source material components in the crucible (namely, metal gallium, iron nitride, and an intermetallic compound of gallium and iron) were removed with aqua regia; thus, a reaction product was isolated. Next, an X-ray diffraction analysis of the reaction product was performed. The results are shown in FIG. 8. A peak derived from a gallium nitride single crystal was not observed at a reaction temperature of 750° C., but a peak corresponding to GaN(0 0 2) was observed at reaction temperatures of more than or equal to 775° C. On the other hand, a conspicuous peak was not observed at a reaction temperature of 750° C. The case where a peak is not observed means that the reaction product is a polycrystalline substance. Thus, it has been found that the upper limit value of the temperature at which the intermediate layer 12 is formed is 750° C.

Next, the lower limit value of the temperature range was checked. Specifically, a crucible filled with the mixed source material was inserted into the tubular furnace, and the mixed source material was held at a reaction temperature of 550° C. for 6 hours. Then, the mass change of the mixed source material during holding (that is, the source material melt) was measured by a thermogravimetric analysis apparatus. As a result, until the reaction temperature reached 550° C., a conspicuous mass change was not observed; however, after the reaction temperature reached 550° C., the mass increased with the lapse of time. It is presumed that the mass increased because nitrogen gas in the atmosphere was incorporated into the source material melt. Further, from the fact that the mass of the source material melt did not saturate immediately, it is presumed that absorbed nitrogen gas reacted with metal gallium and became gallium nitride. When the reaction temperature was set to less than 550° C., such a phenomenon was not observed. As a result, it has been revealed that the lower limit value of the reaction temperature for forming the intermediate layer 12 is 550° C.

### 4. Example 2

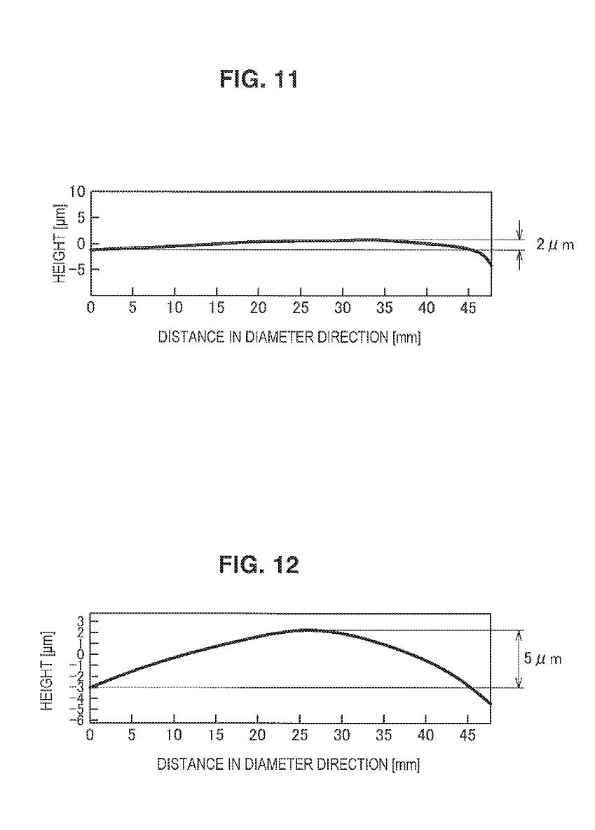

Next, Example 2 corresponding to the second embodiment was performed. In Example 2, treatment similar to the treatment of Example 1 was performed except that the holder 120 used in Example 1 was replaced with the holder 221 shown in FIG. 6. Next, the amount of warpage deformation of the produced gallium nitride stacked body 20 was measured by a non-contact precision external form measuring apparatus (Form Talysurf PGI1250A, produced by Ametek, Inc., Taylor Hobson). The result is shown in FIG. 11. The horizontal axis represents the distance in the diameter direction, that is, the distance in the diameter direction from a measuring point to the outer edge of the gallium nitride stacked body 20. The vertical axis represents the amount of displacement from a prescribed standard value.

Further, as Comparative Example 2, a gallium nitride stacked body in which a gallium nitride single-crystal layer was formed by a vapor phase growth method on only one surface of a sapphire substrate with a diameter of 2 inches, what is called a template substrate (a GaN template substrate with a diameter of 2 inches, produced by Ostendo Technologies, Inc., the U.S.), was prepared. The thickness of the single-crystal layer was set to substantially the same as the total thickness of the intermediate layer 12 and the single-crystal layer 13 (the total thickness of one surface side). Then, the amount of warpage deformation of this template substrate was measured by a non-contact precision external form measuring apparatus. The result is shown in FIG. 12.

As can be seen from the surface form profiles shown in FIG. 11 and FIG. 12, it is found that, in the gallium nitride stacked body 20 according to Example 2, the maximum value of the amount of deformation from a peripheral portion to a central portion of the substrate with a diameter of 2 inches is less than or equal to approximately 2 μm. On the other hand, it is found that, in the template substrate according to Comparative Example 2, a warpage of approximately 5 μm has occurred. Therefore, the radius of curvature of the gallium nitride stacked body 20 according to Example 2 is approximately 156 m when it is assumed that the chord length is 50 mm and the camber is 0.002 mm, and the radius of curvature of the sapphire substrate according to Comparative Example 2 is approximately 62 m when it is calculated similarly to Example 2. Thus, it has been revealed that warpage is reduced by the second embodiment.

The preferred embodiment(s) of the present invention has/have been described above with reference to the accompanying drawings, whilst the present invention is not limited to the above examples. A person skilled in the art may find various alterations and modifications within the scope of the appended claims, and it should be understood that they will naturally come under the technical scope of the present invention.

### REFERENCE SIGNS LIST

10, 20 gallium nitride stacked body
12 intermediate layer
13 single-crystal layer
100 reaction apparatus
110 source material melt
111 reaction vessel
112 base
113 electric furnace
114 heater
120 holder
122 lifting shaft
123 sealing material
131 gas introduction port
132 gas exhaust port

1. A method for producing a gallium nitride stacked body comprising:
an intermediate layer formation step of forming an intermediate layer of gallium nitride with random crystal orientations on a substrate; and
a single-crystal layer formation step of forming a single-crystal layer of gallium nitride on the intermediate layer by a liquid phase epitaxial growth method,
wherein the intermediate layer formation step is a step of forming the intermediate layer on the substrate by a liquid phase epitaxial growth method, and includes
a step of heating metal gallium and iron nitride in a nitrogen atmosphere to a heating temperature of 550 to 750° C., thereby preparing a source material melt, and
a step of immersing the substrate in the source material melt for more than or equal to 1 hour, with the heating temperature set constant.

2. The method for producing a gallium nitride stacked body according to claim 1,
wherein the single-crystal layer formation step includes
a step of heating metal gallium and iron nitride in a nitrogen atmosphere to a heating temperature of more than 750° C., thereby preparing a source material melt, and
a step of immersing, in the source material melt, the substrate on which the intermediate layer is formed.

3. The method for producing a gallium nitride stacked body according to claim 2,
wherein the iron nitride contains any one or more selected from the group consisting of tetrairon mononitride, triiron mononitride, and diiron mononitride.

4. (canceled)

5. (canceled)

6. The method for producing a gallium nitride stacked body according to claim 1,
wherein the iron nitride contains any one or more selected from the group consisting of tetrairon mononitride, triiron mononitride, and diiron mononitride.

7. The method for producing a gallium nitride stacked body according to claim 1,
wherein a thickness of the intermediate layer is less than or equal to 150 nm.

8. The method for producing a gallium nitride stacked body according to claim 1,
wherein the intermediate layer and the single-crystal layer are formed on both surfaces of the substrate.
